(19) United States
(12) Patent Application Publication
(10) Pub. No.: US 2002/0092672 A1
(43) Pub. Date: Jul. 18, 2002

(54) Contact pads and circuit boards incorporating same

(76) Inventor: Anthony A. Primavera, Windsor, NY (US)

Correspondence Address: Chris Johnson, Esq., UNIVERSAL INSTRUMENTS CORP., P.O. Box 825, Binghamton, NY, 13902-0825, US

(21) Appl. No.: 10/040,359

(22) Filed: Jan. 9, 2002

Related U.S. Application Data
(60) Provisional application No. 60/262,238, filed on Jan. 16, 2001.

(51) Int. Cl. H05K 7/06

(52) U.S. Cl. 174/250; 174/253

(57) ABSTRACT

A contact pad for a circuit board includes a central portion; and a plurality of spokes extending from the central portion. A circuit board includes a nonconductive substrate; a plurality of electrically conductive contact pads, each of the contact pads having a central portion; and a plurality of spokes extending from the central portion; and an electrically conductive trace interconnecting the contact pads.

### CROSS-REFERENCE TO RELATED APPLICATIONS

This application claims the benefit of provisional application, Ser. No. 60/262,238, filed at the U.S. Patent and Trademark Office on Jan. 16, 2001.

### BACKGROUND OF THE INVENTION

1. Field of the Invention

The present invention relates to contact pads on a circuit board substrate, and circuit board including such contact pads.

2. Description of Related Art

A typical electronic device includes a plurality of electronic components that are soldered to, or otherwise electrically connected to, a printed circuit board (PCB). Such circuit boards can be of many different types, including those made from a ceramic substrate, or an epoxy or acrylic board. To interconnect the electronic components secured to the circuit board, a plurality of metallic traces are formed on the circuit board. Contact pads are provided along the traces. Copper is the most commonly used conductor on printed circuit boards.

Each contact pad constitutes a location that is intended to receive and be electrically connected to a contact on an electronic component or some other electrical device, such as a connector. In some situations, the contact pad is merely a location where the metallic trace is made wider in order to provide enough room to receive either a wire lead or a contact portion of the electronic component. In other examples, the contact pad may include a metallic buildup that is thicker than the adjacent metallic trace.

Application Specific Integrated Circuits (ASIC) are frequently packaged in an area array device. The two most common types of area array devices are Ball Grid Arrays (BGA) and Chip Scale Packages (CSP). Area array devices in general utilize spheres of solder as the interconnection termination to provide both a physical and electrical connections to the PCB. As with leaded devices, additional solder may be externally supplied to the PCB pad for attachment of the solder ball to the PCB.

The solder ball on the area array device may have a composition near the eutectic (63/37) Sn/Pb mixture point, or have a higher lead (Pb) concentration (5/95) Sn/Pb or (10/90) Sn/Pb. The higher lead concentration raises the melting point to over 300° C. The high lead alloy is used in applications that require the solder to not melt in a standard surface mount technology (SMT) assembly process. Since the area array device has no external leads, all thermally induced (coefficient of thermal expansion (CTE) mismatch) strains must be accommodated by the solder ball or within the package and or PCB structure. When comparing peripheral leaded devices to area array devices, there is often a large difference in the thermal cycle reliability of a comparable size device.

The present invention has primary, but not exclusive, applicability to circuit boards in which the electronic components are directly secured to the printed circuit board by means of a solder ball, i.e., without wired leads. In such an example, a conventional contact pad is generally circular in shape. However, in some situations the contact pad may be trimmed back in certain areas so as to form a somewhat square or rectangular area in order to provide more space for adjacent, but unconnected, traces. FIG. 1 illustrates a plan view of a portion 8 of a conventional circuit board, wherein a plurality of metallic traces 10 are shown. Located periodically amongst the metallic traces 10 are a plurality of contact pads 12.

FIG. 2 is a cross-sectional view taken through a portion of the conventional circuit board of FIG. 1. As can be seen in FIG. 2, the contact pad 12 typically includes a raised portion so that the contact pad 12 is thicker than the adjacent metallic trace 10.

Conventional circuit boards also typically include a dielectric mask to cover the traces in areas that do not include contact pads. The dielectric mask may be made up of any nonconductive material, such as epoxy or acrylic. The mask 14 is placed over the dielectric traces 10 in order to protect the traces 10 from damage. The mask 14 protects the traces 10 from being damaged as a result of being hit during assembly or shipping. In addition, the dielectric mask 14 also helps minimize the likelihood that the trace 10 may peel off the printed circuit board.

The conventional masks have been designed in a number of different ways. For example, FIG. 3 illustrates a mask 14, wherein the mask is adjacent to, but slightly separated from the contact pad 12. Such a mask design has the advantage in that it does not interfere with the application of the solder ball 16 to the contact pad 12. However, it suffers from the disadvantage that it does not help protect the contact pad 12, or prevent the contact pad 12 from being separated from the circuit board 8. The FIG. 3 embodiment is referred to as a Non-Solder Mask Defined (NSMD) geometry, because the mask does not define the exposed area of the contact pad.

Another embodiment of a conventional mask includes a mask 14 that encroaches upon and covers an outer periphery of the contact pad 12. See FIG. 4 for a cross-sectional view of such a mask. The mask of FIG. 4 has the advantage in that it helps protect the contact pad 12 and minimizes the likelihood that the contact pad 12 may be separated from the circuit board. However, the abrupt corners 15 of the mask create stress points on the solder ball 16, and contribute to undesired failure of the solder ball 16 after the component has been secured to the circuit board.

A third embodiment of a conventional mask 14 is illustrated in FIG. 5. In the third embodiment, the sharp corners of the mask 14 are trimmed back to minimize the generation of stress points on an attached solder ball 16. However, such an embodiment involves time consuming and expensive processing.

The FIG. 4 and 5 embodiments are referred to as Solder Mask Defined (SMD) geometries, because the mask defines the exposed area of the contact pad. Although the SMD embodiments have better peel characteristics, the interface between the contact pad and the solder ball is limited by the mask. In particular, the solder ball is not able to make contact with some or all of the edge portion of the contact pads in SMD geometries.

In general, SMD embodiments have better peel strength characteristics, and NSMD designs have better fatigue resistance than SMD designs.

The design and size of a contact pad have competing interests. Specifically, if the contact pad is too small, there is insufficient surface area to which the solder ball may form a good connection. Alternatively, if the contact pad is too large, during application of the component, the solder in the solder ball will flow to substantially uniformly cover the contact pad. Therefore if the contact pad is too large, i.e., has too large a surface area, the solder ball will be spread too thin, and the component will be applied too close to the circuit board.

### OBJECTS AND SUMMARY

It is an object of the present invention to provide a contact pad of a size that optimizes adhesion characteristics with a solder ball attached thereto.

It is another object of the present invention to provide a contact pad of a geometry that optimizes adhesion characteristics with a solder ball attached thereto.

It is a further object of the present invention to provide a contact pad of a shape having optimal characteristics for adhesion to a solder ball connected thereto.

According to one aspect of the invention, a contact pad for a circuit board comprises a central portion; and a plurality of spokes extending from the central portion.

According to yet another embodiment of the present invention, a contact pad for a circuit board comprises a substantially circular portion; and means extending from the substantially circular portion for providing additional surface area of the contact pad to which a solder ball may attach.

The present invention also relates to a circuit board comprising a nonconductive substrate; a plurality of electrically conductive contact pads, each of the contact pads having a central portion; and a plurality of spokes extending from the central portion; and an electrically conductive trace interconnecting the contact pads.

### BRIEF DESCRIPTION OF THE DRAWINGS

FIG. 1 is a plan view of a conventional circuit board having traces and contact pads thereon.

FIG. 2 is a cross-sectional view of the circuit board of FIG. 1.

FIG. 3 is a cross-sectional view of a first embodiment of a conventional contact pad with an adjacent mask.

FIG. 4 is another embodiment of a conventional circuit board having a contact pad and mask thereon.

FIG. 5 is another embodiment of a conventional circuit board having a contact pad and mask thereon.

FIG. 6 includes a plurality of plan views of different designs for contact pads.

FIG. 7 is a plan view of a particular embodiment of a contact pad according to the present invention.

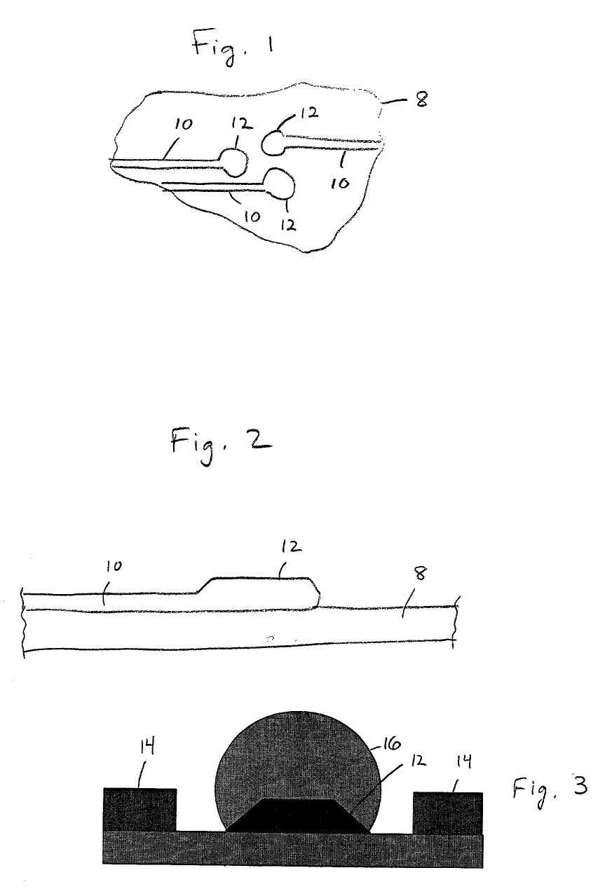

### DETAILED DESCRIPTION OF THE PREFERRED EMBODIMENTS

The present invention is the culmination of an extensive research project directed toward optimizing the design, size, and shape of contact pads on a circuit board. The initial results of the research were compiled and filed as provisional application, Serial No. 60/262,238, with the U.S. Patent and Trademark Office on Jan. 16, 2001. The entire contents of the provisional application are hereby incorporated herein by reference.

The contact pads described herein primarily relate to metallic contact pads on a printed circuit board, which are intended to receive solder balls for connecting the contact pads to contact sites on electronic components. The printed circuit boards may be of any conventional type, including ceramic, epoxy, or acrylic. In addition, the circuit boards may be either rigid or flexible. The present invention is not limited to the specific contact pads and circuit boards described herein. Specifically, the principles of the present invention may be applicable to contact pads or circuit boards other than those described herein.

Certain concepts that were deemed useful in the present invention include increasing the area of solder to pad adhesion, minimizing the area of the contact pad diameter, increasing crack propagation length and direction, maintaining contact pad design simplicity, and increasing the thermal fatigue resistance of the assemblies.

With regard to the first concept, i.e., increasing the area of solder to pad adhesion, one way in which this can be increased is to use a noncircular shape for the contact pad. By changing the shape of a pad from circular to noncircular, the perimeter of the contact pad can be increased. Since the pad has a height dimension, the perimeter or edge of the pad adds significant surface area to which the solder can connect. Thus, using a noncircular design to increase the perimeter of the pad will increase the area of the pad to which the solder can adhere.

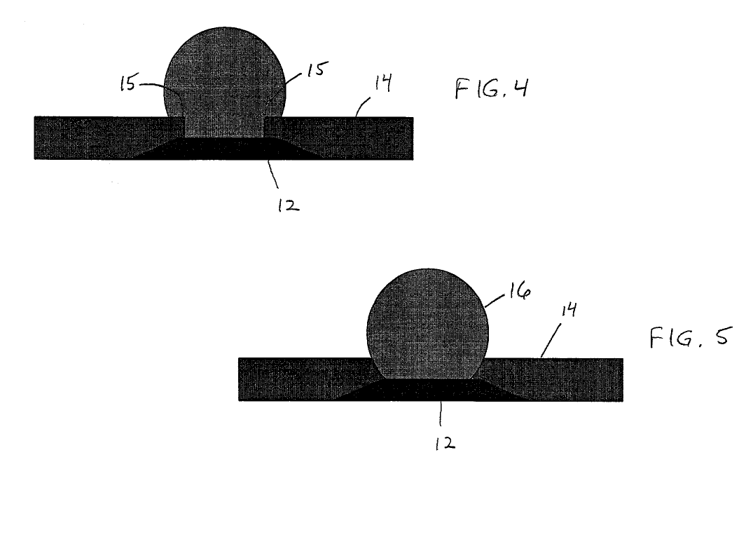

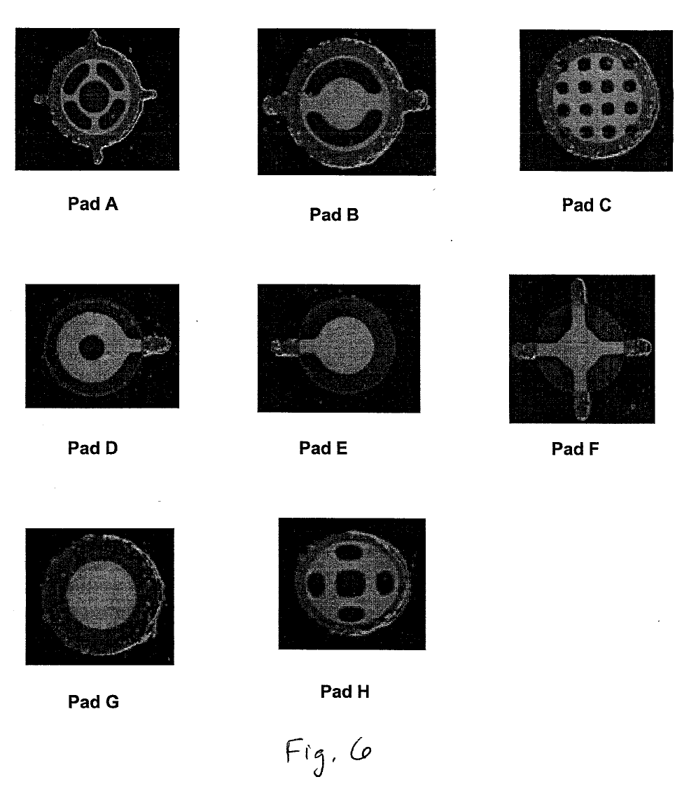

In addition to increasing the surface area, the perimeter or edge areas of the contact pad also have the advantage that they require a propagating crack to change direction as it progresses through the solder ball. In a solder ball mounted on a SMD pad, such as is illustrated in FIGS. 4 or 5, a crack will likely propagate horizontally along the top plane of the contact pad 12. However, in a NSMD pad, such as that illustrated in FIG. 3, a crack will likely begin its propagation at the base of the solder ball, i.e., where the solder ball meets the circuit board. The crack will then work its way up along the edge surface of the pad 12. At the top of the pad, the crack will likely have to change direction and then propagate horizontally along the top surface of the pad, and then down again on the other side of the pad. Thus, a contact pad having an edge or perimeter, not only provides increased surface area to which the solder ball may adhere, it also requires the crack propagation to change direction and increase length before the solder ball becomes dislodged.

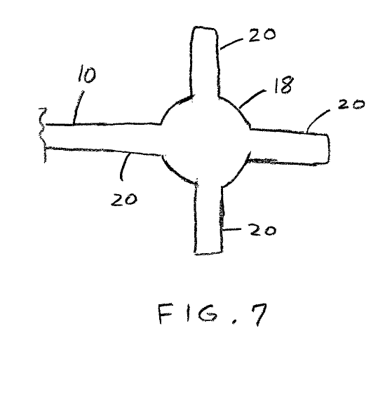

Initial research focused on contact pads that had a maximum amount of side or edge areas. Two approaches were taken. One approach involved increasing the side or edge area by including open spaces in the center of the contact pad. See, for example, the contact pads illustrated in FIG. 6, including the waffle-shaped contact pad illustrated as Pad C. The second approach involved including extensions of the contact pad from a central portion thereof. See, for example, the contact pad illustrated as Pad F.

Although it was found that Pad C of FIG. 6 met many of the goals of the present invention, it was also found that a contact pad pattern that included spaces in the center thereof exposed areas of the PCB. Such designs had the disadvantage in that the exposed portions of the PCB may expell moisture and volatiles which can cause voids during the reflow. Accordingly, design emphasis was on the second approach, i.e., creating contact pads having as much surface area as possible on the outside of the contact pad.

FIG. 7 is a plan view of a portion of a circuit board having traces and a contact pad according to the principles of the present invention thereon. Although not illustrated in the figure, the trace 10 continues on a portion of the circuit board not illustrated in the figure, and the trace 10 connects with another trace and/or another contact pad. The contact pad illustrated in FIG. 7 has a central portion 18 that is substantially circular. Extending from the substantially circular central portion 18 are four spokes 20. In the illustrated embodiment, one of the spokes continues into the aforementioned trace 10, which extends onwardly and makes electrical contact with other traces and/or contact pads.

In the preferred exemplary embodiment, the substantially circular central portion has a height of about 0.025 to 0.076 mm (preferably about 0.050) and a diameter of approximately 0.4 to 0.5 mm. In addition, each of the spokes has a width of approximately 0.100 to 0.125 mm, and extends for a distance of approximately 0.15 to 0.20 mm from the outer perimeter of the substantially circular central portion. Thus, the preferred embodiment of the contact pad has a diameter of about 0.8 mm at its greatest portion, reaching from the far end of one spoke to the far end of an opposite spoke. The disclosed contact pad thus has a total surface area of about 0.387 square mm, including the surface area created by the edge or perimeter of the pad.

The size and shape of the disclosed contact pad is merely an exemplary embodiment, and the principles of the present invention may be applied to other contact pads of different sizes and shapes. According to one aspect of the present invention, a contact pad has a shape so as to increase or maximize the amount of edge area of the contact pad as compared to a substantially circular contact pad covering the same area. For example, a shape used by Pad C, illustrated in FIG. 6, may have a perimeter that is about 14% larger than a circle having a diameter that is about the same as the distance from one spoke tip to an opposite spoke tip of the spoke shaped pad C. Alternative designs could be conceived by those of skill in the art, wherein the perimeter may be 5, 10, 20, or 30% larger than a circular diameter. Specifically, the present invention also includes a contact pad having a perimeter that is longer in length than the circumference of a circle having a diameter that is equal to the distance between the two points on the perimeter of the contact pad that are farthest away from each other. In particular, the perimeter of the contact pad is preferably 5, 10, 15, 20, or 30% longer than the diameter.

It should also be readily apparent to one of skill in the art that the size of the contact pad should have some bearing to the size of the solder ball connected thereto. In the present disclosed embodiment, the contact pad is an ideally designed for use with a solder ball having a nominal diameter of about 0.76 mm.

Contact pads according to the preferred embodiments of the present invention that are disclosed above are made from copper. In another embodiment, the copper contact pads may be covered with a thin layer of nickel, that is about 0.00051 mm thick. The thin layer of nickel is covered with a thin layer of gold, that is about 0.000051 mm thick. The layers of nickel and gold are intended to prevent oxidation or corrosion of the contact pad prior to mounting of the solder ball. However, the present invention is not limited to contact pads of any particular materials.

In an alternative embodiment, the contact pad may have a different number of spokes. For example, contact pads according to the present invention may have 2, 3, 4, 5, 6, 7, 8, or more spokes. The spokes are either symmetrically arranged around the pad center, or, can be arranged in an irregular pattern to facilitate a unique circuit board design.

In another embodiment, contact pads according to the present invention may have internal spaces in them to increase the pad edge area. For example, the contact pad of FIG. 7 may be combined with the waffle pattern of pad C in FIG. 6. In other words, the central portion 18 of the FIG. 7 embodiment may be provided with one or more openings to maximize edge areas.

In addition, in alternative embodiments, the present invention can include contact pads of additional shapes. See, for example, pads A, B, C, D, and H of FIG. 6. Although, for purposes of manufacturing efficiency, it is preferred that the design of the contact pad be simple, complex and irregular patterns may be used in contact pads according to the present invention.

The pads illustrated in FIG. 6 were tested. Shear testing of the solder ball assemblies was done at room temperature using a 5500 series Instron Material Testing Machine. The load cell used for all testing had a maximum capacity of 1 kN. The test apparatus for the solder ball shear on the Instron used a slide mechanism which translated the vertical compressive force generated into a horizontal compressive force by use of bearings. A cylindrical rod, 30 mils in diameter is mounted on the edge of the horizontal beam. There is a platform beyond the rod where the test component is placed. The component to be tested is held in place by a ledge at the end of the base and secured with vacuum. Once the component is placed on the platform, the rod height is adjusted to a height of about of 3 mils from the top of the PCB surface. At this height, the ball was cleanly sheared off. If the height was too high on the ball, the ball would roll rather than shear. The Instron cross head was programmed to move down at a rate of 0.02 inches per minute (20 mils/minute). The test was stopped when the ball was pushed off the pad. In previous testing, the stiffness of the fixture was found to be negligible for loads below 100 lbs. This was done by shear testing a steel block and recording the fixture play, and subsequent compressive stiffness. For each ball sheared, the maximum load, the displacement at maximum load, maximum displacement and the mechanical energy were recorded.

Once the ball was sheared off and the machine reached the break detect point, the cross-head was returned to the start position and the next ball to be sheared was lined up. The sheared solder was analyzed in terms of the type of failure mode, which identified whether the pad failed at the laminate interface, within the bulk solder, or a combination of the two. The shear testing showed a mixture of failure modes and without careful analysis of the data, misidentification of acceptable pad geometries could occur. The data for each pad suggests the design used for Pad F in FIG. 6 had 25% to 50% failures, while all other pad designs tested had shear or pad failures greater than 50%.

Although the contact pads of the preferred embodiments of the present invention are preferably made of copper, other materials can be used that would be well known to those of ordinary skill in the art.

As illustrated in FIG. 6, the dark ring about the outer perimeter of the pads is a dielectric solder mask, such as the type illustrated by reference numeral 14 in FIGS. 3-5. Accordingly, the contact pads of some of the preferred embodiments of the present invention are partially solder mask defined (SMD), at least at the outer periphery thereof. Such masks are also nonsolder mask defined at inner peripheral portions thereof, thus providing edge or periphery surfaces with which the solder ball may engage.

With regard to pad F in FIG. 6, the outer tips of the spokes are covered with a solder mask. However, the remainder of the pad is not covered with a solder mask. Such a configuration provides good resistance to peel, while also providing sufficient edge or perimeter area to which the solder ball may engage.

However, the present invention may also apply to contact pads that have no mask on them, or to contact pads having different portions thereof covered by a mask.

While the present invention has been described by reference to the above-mentioned embodiments, certain modifications and variations will be evident to those or ordinary skill in the art. Therefore, the present invention is limited only by the scope and spirit of the appended claims.

What is claimed is:

1. A contact pad for a circuit board, the contact pad comprising:
a central portion; and
a plurality of spokes extending from the central portion.

2. The contact pad of claim 1, wherein the central portion is substantially circular.

3. The contact pad of claim 1, wherein each of the plurality of spokes is substantially rectangular in shape.

4. The contact pad of claim 1, wherein one of the plurality of spokes is electrically connected to a metallic trace on the circuit board.

5. The contact pad of claim 1, wherein the circuit board is a printed circuit board.

6. The contact pad of claim 1, wherein there are four spokes extending radially outwardly from the substantially circular portion.

7. The contact pad of claim 1, wherein the plurality of spokes are substantially evenly spaced around the substantially circular portion.

8. The contact pad of claim 1, further comprising a solder mask at outer tips of the spokes.

9. The contact pad of claim 1, wherein contact pad is made of a conductive material.

10. A contact pad for a circuit board, the contact pad comprising:
a central portion; and
means extending from the central portion for providing additional surface area of the contact pad to which a solder ball may attach.

11. The contact pad of claim 10, wherein the central portion includes an opening in a center thereof.

12. A contact pad for a circuit board, the contact pad comprising:
a substantially circular portion; and
means extending from the substantially circular portion for providing additional surface area of the contact pad to which a solder ball may attach.

13. The contact pad of claim 12, wherein the substantially circular portion includes an opening in a center thereof.

14. A circuit board, comprising:
a nonconductive substrate;
a plurality of electrically conductive contact pads, each of the contact pads having a central portion; and a plurality of spokes extending from the central portion; and
an electrically conductive trace interconnecting the contact pads.

15. The circuit board of claim 14, wherein the central portion is substantially circular.

16. The circuit board of claim 14, wherein each of the plurality of spokes is substantially rectangular in shape.

17. The circuit board of claim 14, wherein one of the plurality of spokes is electrically connected to the trace on the circuit board.

18. The circuit board of claim 14, wherein the circuit board is a printed circuit board.

19. The circuit board of claim 14, wherein each of the contact pads has four spokes extending radially outwardly from the substantially circular portion.

20. The circuit board of claim 14, wherein on at least one of the contact pads, the plurality of spokes are substantially evenly spaced around the substantially circular portion.

21. A contact pad for a circuit board, the contact pad comprising a conductive material arranged in a shape having a perimeter that is at least 5% longer in length than a circumference of a circle having a diameter that is equal to a distance between the two points on the perimeter of the contact pad that are farthest away from each other.

22. The contact pad of claim 21, wherein the perimeter is at least 10% longer than the diameter.

23. The contact pad of claim 21, wherein the perimeter is at least 15% longer than the diameter.

24. The contact pad of claim 21, wherein the perimeter is at least 20% longer than the diameter.

25. The contact pad of claim 21, wherein the perimeter is at least 30% longer than the diameter.
